(19) United States
(12) Patent Application Publication
(10) Pub. No.: US 2002/0137333 A1
(43) Pub. Date: Sep. 26, 2002

(54) Method for fabricating an integrated circuit with a dynamic memory cell configuration (DRAM) with a long retention time

(76) Inventor: Markus Kirchhoff, Ottendorf-Okrilla (DE)

Correspondence Address: LERNER AND GREENBERG, P.A., POST OFFICE BOX 2480, HOLLYWOOD, FL, 33022-2480, US

(21) Appl. No.: 10/106,590

(22) Filed: Mar. 26, 2002

(30) Foreign Application Priority Data
Mar. 26, 2001 (DE) 101 14 764.3

(51) Int. Cl. H01L 21/44; H01L 21/26; H01L 21/324; H01L 21/477; H01L 21/42; H01L 21/336

(52) U.S. Cl. 438/677; 438/798; 438/660; 438/308

(57) ABSTRACT

In order to fabricate a dynamic memory cell configuration with a long retention time, a hydrogen heat treatment of the wafer is carried out after the production of the interconnect system. The hydrogen heat treatment is performed in a PECVD reactor into which hydrogen is introduced and excited in the plasma. The heat treatment becomes more effective as a result and can be combined with deposition processes, in particular of passivation layers, carried out in PECVD installations.

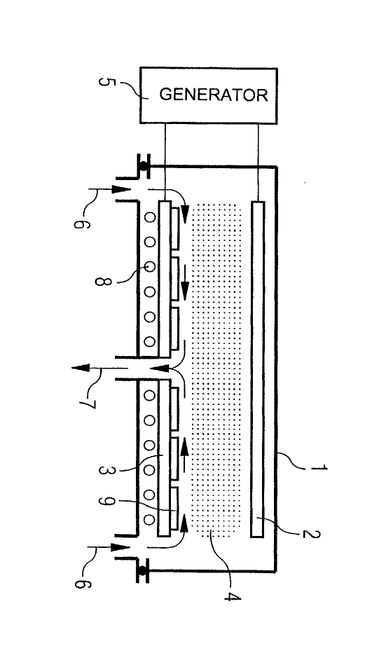

### BACKGROUND OF THE INVENTION

1. Field of the Invention

The invention lies in the integrated technology field. More specifically, the invention relates to a method for fabricating an integrated circuit with a dynamic memory cell configuration (DRAM) with a long retention time, in which a hydrogen heat treatment of the wafer is carried out after the production of the interconnect system.

A method of this type is described in U.S. Pat. No. 6,077,778.

In principle, dynamic memory cells are constructed very simply. They comprise merely a selection transistor and a storage capacitor. The memory states “0” and “1” correspond to the positively and negatively charged capacitor, respectively. After each read operation, the information must be written in again, i.e. the charge must be refreshed. Even without read operations, the capacitor charge must be repeatedly refreshed regularly, since, in contemporary memory cells, it is reduced in a time of a few milliseconds to approximately 1 second on account of recombination and leakage currents. The “refresh” is effected automatically with the aid of a circuit that is integrated on the chip. The special feature of the “refresh” has given the memory constructed from a multiplicity of memory cells the name “dynamic memory” (DRAM=Dynamic Random Access Memory).

In many memory cell configurations, the maximum time interval after which information stored in a memory cell must be refreshed is essentially determined by the magnitude of the leakage currents. This time interval is also referred to as retention time.

It is generally endeavored to increase the retention time, in particular with regard to memory cell configurations which are provided for battery-operated devices, such as e.g. for portable computers. In fact, the art has achieved (at least) doubling of the retention time approximately at the same interval as the successive DRAM memory generations. The 1 Mbit, for example, already had a typical retention time of 8 ms, while nowadays a few hundred milliseconds are deemed desirable and achievable.

However, as the “structural density” of the DRAM memories increases, it becomes more and more difficult to realize or actually even increase the desired high retention times. It is known that the problematic leakage currents occur in particular in connection with defects in the structure of the monocrystalline silicon substrate or interface states. By way of example, such imperfections increasingly have to be reckoned with when fabricating the relatively deep trench for the capacitor. It is also known that hydrogen can, to a certain degree, saturate free bonds of the silicon atoms and anneal defects. Therefore, a heat treatment (anneal) with hydrogen gas excited thermally in the furnace is carried out in many cases in order to reduce the leakage currents. These heat treatments are usually carried out at normal pressure in tubular furnaces with relatively slow heating up and cooling down, as are also used for thermal oxidation.

The above-mentioned U.S. Pat. No. 6,077,778 discloses such a hydrogen heat treatment. There, the retention time of a DRAM is increased by performing, after the production of an interconnect system comprising the materials tungsten or aluminum, a heat treatment of this interconnect system at a temperature of between 400 and 500° C. in flowing forming gas. Forming gas comprises a gas mixture of hydrogen and a (non-critical) proportion of nitrogen, which is added for safety reasons. This known hydrogen heat treatment is intended on the one hand to last at least 30 minutes, while on the other hand the effectiveness of the method, in particular with regard to increasing the retention time, is not increased even by heat treatment for 60 or 90 minutes.

### SUMMARY OF THE INVENTION

It is accordingly an object of the invention to provide a method for fabricating an integrated circuit with a dynamic memory cell configuration (DRAM) with a long retention time, which overcomes the above-mentioned disadvantages of the heretofore-known devices and methods of this general type and which can be used to carry out a hydrogen heat treatment which is more efficient but at the same time is also optimized as far as possible with regard to the process control.

With the foregoing and other objects in view there is provided, in accordance with the invention, a method of fabricating an integrated circuit with a dynamic memory cell configuration with a long retention time, which comprises:

producing an interconnected system of the integrated circuit on a wafer;

introducing hydrogen into a PECVD reactor and exciting the hydrogen in the plasma to form hydrogen ions; and

carrying out a hydrogen heat treatment of the wafer with the hydrogen ions accelerated in the plasma alternating field.

In accordance with an added feature of the invention, a passivation layer is deposited after the hydrogen plasma heat treatment in the same PECVD reactor.

In accordance with a concomitant feature of the invention, the hydrogen plasma heat treatment is carried out before and after the deposition of the passivation layer, and the process sequence of the three individual processes is thereby performed in the same PECVD reactor.

In other words, the objects of the invention are achieved by virtue of the fact that the hydrogen heat treatment is carried out in a PECVD reactor into which hydrogen is introduced and excited in the plasma.

The invention is based on the insight that in the case of the conventional heat treatment in the furnace, the thermally excited hydrogen molecules have to separate into hydrogen atoms on the way from the furnace through the wafer surface as far as the substrate, in order to be able to fulfill their annealing function. In particular, a silicon atom requires a single hydrogen atom in order to saturate a free bond. The hydrogen plasma heat treatment according to the invention makes it possible to offer hydrogen atoms from the outset for the annealing processes in the wafer, the number or reactivity of said hydrogen atoms, and thus the effectiveness of the annealing processes, being controllable at least in part by the parameters of the PECVD (Plasma Enhanced Chemical Vapor Deposition) reactor. The effectiveness can be increased in different respects and by different mechanisms. In many cases, the hydrogen plasma heat treatment can saturate imperfections which are not saturated by means of conventional furnace technology. This normally results in a longer retention time. The hydrogen plasma heat treatment can also have the result that the hydrogen atoms can diffuse more rapidly and/or penetrate more rapidly into the wafer on account of acceleration in the plasma alternating field and thereby anneal imperfections more rapidly or down to a greater substrate depth. The different effects specifically depend greatly on the chip design, that is to say on what structures were produced with what process technology on the respective wafer.

In addition to increasing the effectiveness of the heat treatment process, the plasma excitation of the hydrogen in a conventional PECVD reactor opens up possibilities for process simplification, since the hydrogen heat treatment no longer has to take place in the furnace, but rather can be combined in PECVD installations with deposition processes that are carried out there.

Accordingly, a particularly advantageous refinement of this method consists in a passivation layer being deposited after the hydrogen plasma heat treatment in the same PECVD reactor.

Other features which are considered as characteristic for the invention are set forth in the appended claims.

Although the invention is illustrated and described herein as embodied in a method for fabricating an integrated circuit with a dynamic memory cell configuration (DRAM) with a long retention time, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE DRAWING

The sole FIGURE is a diagrammatic sectional view of a PECVD reactor.

### DESCRIPTION OF THE PREFERRED EMBODIMENTS

During the fabrication of integrated circuits, a hydrogen plasma heat treatment can be carried out, in a similar manner to previously, in the so-called BEOL (Back End Of Line) module in direct temporal connection with the “final passivation,” i.e. the fabrication of the final dielectric diffusion barrier for protecting the chip. At this point there is advantageously a process sequence of three individual processes (a single hydrogen plasma heat treatment before or after the deposition of the passivation layer is also possible, of course):

a) hydrogen plasma heat treatment

b) final passivation

c) hydrogen plasma heat treatment

which are combined according to the invention into one process. To that end, the two hydrogen plasma heat treatments take place not in the furnace but in the same PECVD reactor chamber which also deposits the layers of the final passivation. By way of example, a layer system known per se comprising silicon oxide/silicon nitride or a silicon oxynitride can be used as the passivation layer. The hydrogen plasma heat treatment is carried out before the final passivation and is then repeated again after the deposition of the dielectric layer.

Before and after the deposition of this (these) passivation layer(s), hydrogen is introduced into the reactor chamber and partly decomposed in the plasma. The atomic hydrogen thus formed passivates the free bonds (dangling bonds) in the substrate significantly more rapidly and more effectively than the molecular hydrogen present in a conventional furnace also because the atom (ion) receives from the alternating electric field which generates the plasma a kinetic energy in the direction of the substrate, thereby substantially facilitating the physical penetration of the hydrogen as far as the substrate. Therefore, in particular, PECVD parallel plate reactors or other plasma excitation installations known from semiconductor technology are appropriate, but not so much reactors with a separate plasma source, since the latter do not provide any accelerated ions at the wafer.

Referring now to the sole FIGURE of the drawing in detail, the parallel plate reactor 1 has top and bottom electrodes 2 and 3. The high-frequency voltage of the generator 5 which is applied to the electrodes 2 and 3 brings the gas to corona discharge and a plasma 4 is produced with ions, electrons and excited neutral particles (radicals). In contrast to the ions, the electrons, which are lighter by comparison therewith, can follow the high-frequency field (e.g. approximately 13.3 MHz) between the electrodes 2 and 3. This has the result, in a manner known per se, that significantly more electrons than ions reach the electrodes 2 and 3 during the high-frequency half-cycles. As a result they are charged negatively and thus attract the positive hydrogen ions from the plasma 4, as a result of which these achieve a kinetic energy whose magnitude depends in particular on the type of reactor. The FIGURE furthermore shows the gas inlet 6, the extraction 7, the heating 8 (the heat treatment temperature is typically 400° C.) and the wafer 9 situated on the bottom electrode 3.

The path of the hydrogen atoms into the substrate also depends in particular on the respective DRAM technology. The interconnect system may be formed for example from two aluminum planes and one tungsten plane, beneath which there is a stacked capacitor on polysilicon, so that the hydrogen atoms have to cover about 2 μm to reach the actual substrate. In the case of trench capacitors, on the other hand, it must be taken into account that penetration of the hydrogen as far as the substrate surface does not suffice to anneal all imperfections. Since the capacitor trench itself also reaches to a depth of approximately 8 μm into the substrate, the hydrogen must travel at least 2+8=10 μm in order to be able to anneal all imperfections, so that the hydrogen plasma heat treatment can be used particularly expediently with this technology.

According to the invention, the process sequence described can take place within one and the same reactor chamber without interruption. This integrated processing affords, in addition to the technological advantage of more effective passivation of substrate defects, in particular an increase in the retention time, economic advantages in the form of obviating furnaces and saving time by avoiding logistical steps and by avoiding the relatively slow furnace steps.

I claim:

1. A method of fabricating an integrated circuit with a dynamic memory cell configuration with a long retention time, which comprises:
producing an interconnected system of the integrated circuit on a wafer;
introducing hydrogen into a PECVD reactor and exciting the hydrogen in the plasma to form hydrogen ions; and
carrying out a hydrogen heat treatment of the wafer with the hydrogen ions accelerated in the plasma alternating field.

2. The method according to claim 1, which comprises depositing a passivation layer after the hydrogen plasma heat treatment in the same PECVD reactor.

3. The method according to claim 2, which comprises carrying out the hydrogen plasma heat treatment before and after the deposition of the passivation layer, and thereby performing the process sequence of the three individual processes in the same PECVD reactor.
